(19) United States
(12) Patent Application Publication
(10) Pub. No.: US 2013/0261999 A1
(43) Pub. Date: Oct. 3, 2013

(54) Ring Ground Testing And Monitoring

(71) Applicant: Brian Keith Brashear, San Antonio, TX (US)

(72) Inventor: Brian Keith Brashear, San Antonio, TX (US)

(73) Assignee: ILD TECHNOLOGIES, LLC, San Antonio, TX (US)

(21) Appl. No.: 13/435,488

(22) Filed: Mar. 30, 2012

(51) Int. Cl. G01R 31/14; G06F 19/00

(52) U.S. Cl. 702/58

(57) ABSTRACT

Systems and methods for ring ground testing and monitoring are disclosed. In some embodiments, a system may include an isolation module configured to: (a) electrically couple a first portion of a ring ground network to a second portion of the ring ground network during normal operation, and to (b) electrically decouple the first portion from the second portion during operation during performance of an electrical test. The system may also include a control module coupled to the isolation module, the control module including an integrated circuit and a memory coupled to the integrated circuit. The memory may be configured to store program instructions executable by the integrated circuit to cause the control module to: instruct the isolation module to enter a test mode, execute an electrical test of the first and/or second portions, indicate a result of the electrical test, and instruct the isolation module to operate in normal mode.

### TECHNICAL FIELD

This specification relates generally to electrical testing and monitoring, and, more particularly, to systems and methods for ring ground testing and monitoring.

### BACKGROUND

A ring ground is a type of electrical ground used to protect buildings and/or electrical equipment from damage caused, for example, due to electrical surges (e.g., lightning strikes, etc.). Generally speaking, a ring ground is constructed from a relatively large wire buried a few feet underground. In the U.S., for instance, the National Electrical Code specifies that ring grounds be constructed from #2 (or thicker) wire, buried at least 2.5 ft. underground, and have at least 20 ft. of exposed copper to ensure electrical contact with the earth.

In a typical installation, ring grounds typically encircle the entire building that they are designed to protect, and are often used as the base of an entire building's ground system. All electrical components within the building, as well as the building structure itself, are connected to the ground ring. As such, ring grounds are commonly used around communications equipment such as cell phone towers, radio towers, and other types of equipment buildings (e.g., computer data centers, etc.).

The inventor hereof has recognized, however, that ring ground networks are subject to damage from various sources (e.g., nearby construction, utility excavation, earthquakes, etc.). Until now, it has been very difficult or nearly impossible to reliably determine that a ring ground network is intact (i.e., unbroken) and fully operational.

### SUMMARY

Embodiments disclosed herein are directed to systems and methods for ring ground testing and monitoring. In an illustrative, non-limiting embodiment, a system may include an isolation module and a control module. The isolation module may be configured to electrically couple a first portion of a ring ground network to a second portion of the ring ground network during operation in normal mode, and it may also be configured to electrically decouple the first portion of the ring ground network from the second portion of the ring ground network during operation in test mode. The control module may be coupled to the isolation module, and it may include an integrated circuit as well as a memory coupled to the integrated circuit. The memory may be configured to store program instructions executable by the integrated circuit to cause the control module to perform one or more operations. For example, the control module may instruct the isolation module to operate in test mode, control execution of an electrical integrity test of at least one of the first or second portions of the ring ground network, indicate a result of the electrical integrity test, and/or instruct the isolation module to operate in normal mode.

In various implementations, the ring ground network may be at least partially buried underground and may be configured to provide an electrical ground adapted to protect a building or equipment from electrical damage. Also, the integrated circuit may include a digital signal processor (DSP), an application specific integrated circuit (ASIC), a system-on-chip (SoC) circuit, a field-programmable gate array (FPGA), a programmable logic controller (PLC), a microprocessor, or a microcontroller.

In some embodiments, to instruct the isolation module to operate in test mode, the program instructions may be executable by the integrated circuit to cause the control module to transmit a first electrical signal to one or more isolation relays within the isolation module, the first electrical signal adapted to open the one or more isolation relays and electrically decouple the first portion of the ring ground from the second portion of the ring ground network. For example, the one or more isolation relays may include one or more 120VAC or 240VAC relays connected to each other in parallel.

Moreover, to control execution of the electrical integrity test of at least one of the first or second portions of the ring ground network, the program instructions may be executable by the integrated circuit to cause the control module to transmit a second electrical signal to a first control relay within the isolation module, the first control relay configured to, upon receipt of the second electrical signal, return a first result signal to the control module in response to the first portion of the ground ring network being electrically unimpaired. Additionally or alternatively, to control execution of the electrical integrity test of at least one of the first or second portions of the ring ground network, the program instructions may be executable by the integrated circuit to cause the control module to transmit a third electrical signal to a second control relay within the isolation module, the second control relay configured to, upon receipt of the third electrical signal, return a second result signal to the control module in response to the second portion of the ground ring network being electrically unimpaired. For instance, the first and/or second electrical signal may be a 120VAC or 240VAC signal, and the first and/or second result signal may be a 12-24VDC signal.

In some cases, to indicate the result of the electrical integrity test, the program instructions may be executable by the integrated circuit to cause the control module to transmit information to a remote computer over a network indicating whether at least one of the first or second portions of the ground ring network is electrically unimpaired. Furthermore, to instruct the isolation module to operate in normal mode, the program instructions may be executable by the integrated circuit to cause the control module to transmit a fourth electrical signal to the one or more isolation relays within the isolation module, the fourth electrical signal adapted to close the one or more isolation relays and electrically couple the first portion of the ring ground to the second portion of the ring ground network.

In another illustrative, non-limiting embodiment, a tangible storage medium may have program instructions stored thereon that, upon execution by a ring ground monitoring system, cause the ring ground monitoring system to transmit a signal instructing an isolation module to electrically decouple a first portion of a ring ground network from a second portion of the ring ground network, cause execution of an electrical test of the first portion of the ring ground network, and receive a result of the electrical test, the result indicative of whether the first portion of the ground ring network is electrically impaired. Additionally or alternatively, the program instructions may cause the ring ground monitoring system to cause execution of another electrical test of the second portion of the ring ground network and receive another result of the another electrical test, the another result indicative of whether the second portion of the ground ring network is electrically impaired.

In some implementations, the program instructions, upon execution by the ring ground monitoring system, may cause the ring ground monitoring system to transmit a signal instructing the isolation module to electrically couple the first portion of the ring ground network to the second portion of the ring ground network. The program instructions, upon execution by the ring ground monitoring system, may also cause the ring ground monitoring system to provide a visual indication of whether first portion of the ground ring network is electrically impaired to a user. Additionally or alternatively, the program instructions may cause the ring ground monitoring system to transmit information of whether the first portion of the ground ring network is electrically impaired over a computer network to a remotely located computer system.

In yet another illustrative, non-limiting embodiment, a method may include performing one or more operations by an isolation module. These operations may include, for example, receiving, from a ring ground monitoring system, a signal instructing the isolation module to electrically decouple a portion of the ring ground network from another portion of the ring ground network. The operations may also include electrically decoupling the portion of the ring ground network from the another portion of the ring ground network. The operations may also include performing, at the control of the ring ground monitoring system, execution of an electrical integrity test of the portion of the ring ground network. The operations may further include providing, to the ring ground monitoring system, a result of the electrical test, the result indicative of whether the portion of the ground ring network is electrically impaired.

In some implementations, performing execution of the electrical test of the portion of the ring ground network may include receiving an alternating current signal at a relay within the isolation module. Additionally or alternatively, providing the result of the electrical test further may include providing a direct current (DC) signal to the ring ground monitoring system upon the relay closing in response to completion of an electrical circuit, the electrical circuit including the portion and excluding the another portion of the ring ground network.

In some embodiments, the method may also include performing, by the isolation module, receiving, from the ring ground monitoring system, a signal instructing the isolation module to electrically couple the first portion of the ring ground network to the second portion of the ring ground network, and then electrically coupling the first portion of the ring ground network to the second portion of the ring ground network.

### BRIEF DESCRIPTION OF THE DRAWINGS

Reference will now be made to the accompanying drawings.

FIG. 1 is a diagram of a ring ground testing and monitoring system according to some embodiments.

FIG. 2 is a diagram of a ring ground network divided into two portions or quadrants according to some embodiments.

FIG. 3 is a diagram of a ring ground network divided into four portions or quadrants according to some embodiments.

FIG. 4 is a diagram illustrating neutral-to-ground signal routing according to some embodiments.

FIG. 5 is a diagram illustrating a test signal's routing or switching according to some embodiments.

FIG. 6 is a block diagram of a testing and monitoring controller configured to implement various systems and methods described herein according to some embodiments

FIG. 7 is an electrical diagram of a control module according to some embodiments.

FIG. 8 is an electrical diagram of an isolation module according to some embodiments.

FIG. 9 is a flowchart of a ring ground testing and monitoring method according to some embodiments.

FIG. 10 is a diagram illustrating a two-isolation module—based system according to some embodiments.

While this specification provides several embodiments and illustrative drawings, a person of ordinary skill in the art will recognize that the present specification is not limited only to the embodiments or drawings described. It should be understood that the drawings and detailed description are not intended to limit the specification to the particular form disclosed, but, on the contrary, the intention is to cover all modifications, equivalents and alternatives falling within the spirit and scope of the claims. Also, any headings used herein are for organizational purposes only and are not intended to limit the scope of the description. As used herein, the word “may” is meant to convey a permissive sense (i.e., meaning “having the potential to”), rather than a mandatory sense (i.e., meaning “must”). Similarly, the words “include,” “including,” and “includes” mean “including, but not limited to.”

### DETAILED DESCRIPTION

This specification discloses systems and methods for ring ground testing and monitoring. Generally speaking, the various techniques described herein may find applicability in a wide variety of environments (e.g., residences, businesses, cell phone towers, radio towers, computer data centers, etc.). Furthermore, although described in some examples as particularly well-suited to test and/or monitor ring grounds, the systems and methods disclosed herein may also be applicable to test and/or monitor other types of grounds or electrical circuits.

Integrity of a ring ground system is essential to proper operation of facility protective devices, zero-point reference networks, and other critical systems. Yet, traditional ground circuit monitoring technologies only inaccurately infer ground integrity by measurement of ground resistance or soil moisture levels. In contrast with these conventional techniques, the systems and methods described herein are specifically designed to test and confirm the electrical integrity of a complete ring ground network, regardless of soil type or condition, ground DC resistance or other factors (e.g., humidity, temperature, etc.).

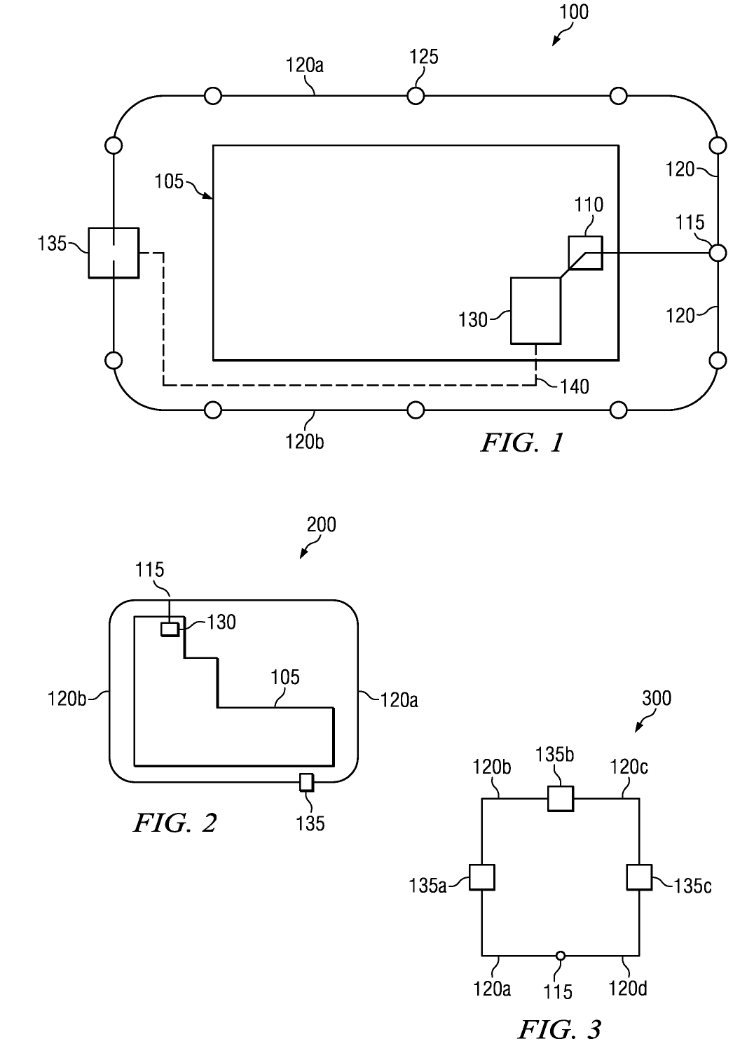

Turning now to FIG. 1, a diagram of ring ground testing and monitoring system 100 is depicted according to some embodiments. As illustrated, building or structure 105 is surrounded by ring ground 120. Main electrical distribution point and ground bus 110 receives electrical power from a power grid (not shown) and is typically physically located within building 105. Main distribution point and ground bus 110 is also coupled to ring ground (or ring ground network) 120 via single attachment point (SP) 115, as prescribed by the U.S. National Electrical Code (NEC). In various embodiments, ring ground 120 may be constructed from #2 (or thicker) copper wire (or the like), buried at least 2.5 ft. underground, and have at least 20 ft. of exposed wire to ensure good electrical contact with the earth. In addition, horizontal metal rods 125 are sometimes installed along the perimeter of ring ground 120.

When ring ground 120 is unbroken and the cable is of adequate size, the entire ground system (including the earth in proximity to ring 120) is equi-potential and at extremely low impedance due to the infinite number of parallel grounding points. All connected devices are at the same potential (ideally, zero voltage) level. Thus, in an ideal equi-potential state there would be no electrical current in the form of ground loops to flow between devices. Incidentally, this is an advantage that ring systems offer over conventional single electrode or limited grid ground systems. Although shown in FIG. 1 as a rounded square or rectangle, it should be noted that the geometry of ring ground 120 can vary greatly with actual facility 105 layout, and that it may not be a perfect geometric shape.

If ring ground 120 sustains damage that results in a break in the copper cabling (e.g., as a result of construction, trenching, excavation, boring operations, earthquakes, sinkhole formation, land subsidence, etc.), however, there can be a loss of the equi-potential state and the protection ring ground 120 is otherwise supposed to provide. As such, the damage may cause serious susceptibility to high frequency/high energy excursions commonly observed in ground fault conditions or near-strike lightning events resulting in Ground Potential Rise (GPR). In some cases, the damage may also cause an increase in overall system impedance seriously affecting performance of all protective devices, including transient voltage surge suppressors. Furthermore, with respect to testing and monitoring of ring ground 120, because its DC resistance tends to remain low at normal conditions (despite the damage sustained), conventional ground monitoring systems often fail to detect the break and facility 105 cannot be alerted that loss of ground integrity has occurred. As a result, if a high current fault or GPR event occurs at a later time, facility 105 is susceptible to significant equipment damage and costs due to the failure of protective devices to operate correctly. To address these and other concerns, the inventor hereof has developed the systems and methods described herein.

Still referring to FIG. 1, isolation panel or module 135 is coupled to ring ground 120 and configured to electrically couple a first quadrant or portion 120a of ring ground 120 to second quadrant or portion 120b when operating in normal mode. Isolation module 135 is also configured to electrically decouple first portion 120a from second portion 120b during operation in test mode. Control module 130 is coupled to isolation module 135 via conductor 140, as well as to main distribution point and ground bus 110. In operation, control module 130 may instruct isolation module 135 to operate in test mode, control execution of an electrical integrity test of first 120a and/or second 120b portions of ring ground 120, indicate a result of the electrical integrity test, and then instruct isolation module 135 to return to normal mode. These and other operations are discussed below.

FIG. 2 is a diagram of ring ground network 200 divided into two portions or quadrants. In some embodiments, ring ground 120 may be divided into portions 120a and 120b of approximately equal length, regardless of the shape of building 105 and/or the shape of ring ground 120. In this manner, if the test and monitoring system detects a problem with one of portions 120a or 120b, the user may be able to more easily identify where the break in ring ground 120 actually is. This is contrast, for example, with positioning isolation module 135 close to SP 115, in which case one of portions 120a or 120b may be much shorter than the other, and a detected problem in the longer one of portions 120a or 120b may be more difficult to be physically located.

FIG. 3 is a diagram of ring ground network 300 divided into four portions or quadrants according to some embodiments. As illustrated, three isolation modules 135a-c are disposed along ring ground 120 and connected to SP 115; thus creating four portions or quadrants 120a-d. It should be noted that, in various embodiments, any arbitrary number of isolation modules may be used. Generally speaking, the greater the number of quadrants (separated by isolation panels), the greater the system's ability to pinpoint the location of a break in ring ground 120. In many cases, because the events leading to ring ground failure are visible (e.g., nearby construction), a single isolation module may be all that is needed. There are other cases, however, where the location of the damage is not self-evident (e.g., near a zone of seismological, coastal, or non-surface events), and therefore it may be beneficial to install additional isolation panels and obtain greater granularity in the ability to locate faults.

To better illustrate some of principles involved in the testing and monitoring systems described below, consider that, in a typical 2-wire alternating current (AC) system, current (I) leaving a power supply (typically the electrical utility distribution system transformer) tries to return to it (e.g., it tries not to go into the earth). Alternating current applied to a transformer primary induces a voltage in the secondary (Vs). This induced voltage causes electrons to leave one end of the transformer secondary, travel over the main power conductor (L1), through the load, and return over the neutral conductor (N) to the other end of the transformer secondary, expending all of the system voltage rise in the process. In the U.S. and in most developed countries, distribution systems utilize a grounded neutral in order to provide a safe low impedance return path to the transformer. The grounding system is typically one or more vertical electrodes driven deeply into the soil adjacent to the main ground bus. However, in a facility utilizing a ring ground system, as shown in FIG. 1, the ground lead is a continuously connected buried bare copper conductor encompassing the entire facility.

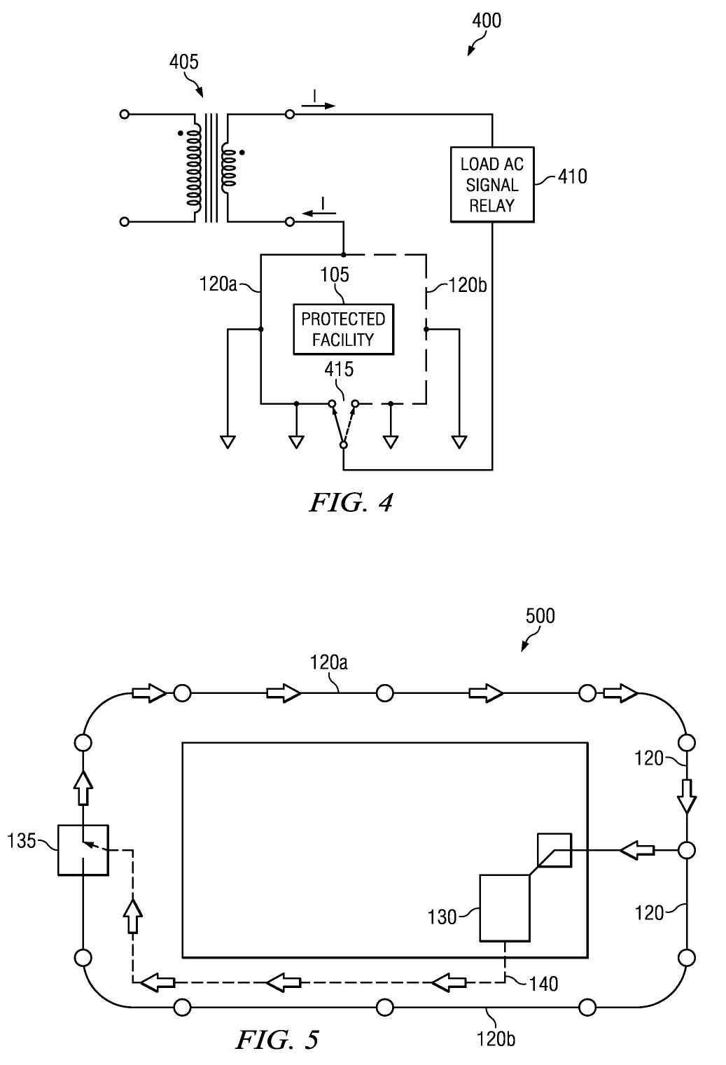

As such, FIG. 4 shows a diagram illustrating neutral-to-ground signal routing 400 that is suitable for testing ring grounds according to some embodiments. Ring ground 120 is connected to the neutral point of the secondary winding of transformer 405 (e.g., through main distribution point 110). A ring ground monitoring system, as described herein, may be designed to bypass the neutral conductor (L2-N) and utilize one of quadrants 120a and 120b of this continuous ring as selected by switch 415 as the return path for current (I) to transformer 405. Load 410 may include a signaling relay that, upon actuation, provides positive indication of a complete circuit, thus confirming integrity of the buried copper conductor for a given selected quadrant.

FIG. 5 is a diagram illustrating a test signal's routing or switching. In some embodiments, at a pre-programmed time interval (e.g., 1-4 times per day), test and monitoring system 500 automatically goes into test mode. Upon command of control module 130, isolation module 135 momentarily breaks ring ground network 120 into two isolated quadrants or portions 120a and 120b. After first time interval, a signal may be injected into portion 120a through conductor 140, utilizing the return path to the through quadrant 120a (as shown by arrows). Failure of this signal to be received by control module 130 is an indication of a break in the copper pathway of portion 120a. Sometime later, the same test may be repeated for portion 120b, after which the system is automatically returned to normal mode and portions 120a and 120b reconnected as before, with ring ground 120 intact and fully operational. It should be noted that, during the entire test, although ring 120 is broken into two portions, the grounding system for each quadrant remains connected to main distribution point and ground bus 110, and continues to operate throughout the procedure. Moreover, in its normal state, there are multiple levels of electrical isolation between the various system components and ring ground 120, ensuring survivability of the monitoring system during a ground fault or GPR event.

If loss of integrity is observed in either or both quadrants 120a or 120b (or in the connection to the main grounding bus 110), control module 130 may alert facility staff of the quadrant's failure, locally (e.g., through a combination of flashing panel LEDs, etc.), via an alarm system, and/or a network signal configured to notify the staff via a computer network.

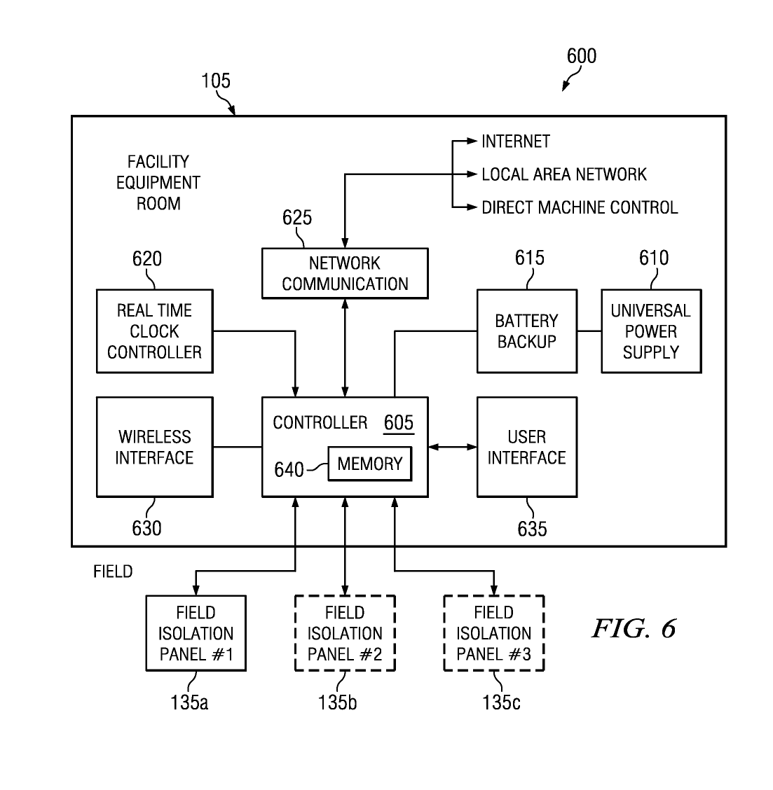

FIG. 6 depicts a block diagram of testing and monitoring controller 600. In some embodiments, testing and monitoring controller 600 may be used, at least in part, to implement control module 130 of FIGS. 1 and 5. As illustrated, controller circuit 605 may be a digital signal processor (DSP), an application specific integrated circuit (ASIC), a system-on-chip (SoC) circuit, a field-programmable gate array (FPGA), a programmable logic controller (PLC), a microprocessor, or a microcontroller. Moreover, controller circuit 605 may include or otherwise be coupled to memory 640. Memory 640 may include any type of semiconductor memory or storage device. For example, memory 640 may include flip-flops, latches, SRAM, nonvolatile RAM (NVRAM, such as “flash” memory), dynamic RAM (DRAM) such as synchronous DRAM (SDRAM), double data rate (DDR, DDR2, DDR3, etc.) SDRAM, etc. In some cases, memory 640 may include one or more memory modules to which the memory devices are mounted, such as single inline memory modules (SIMMs), dual inline memory modules (DIMMs), etc.

Controller circuit 605 may include or otherwise be coupled to clock circuit 620. Controller circuit 605 may also be coupled to one or more of: wired network interface 625, wireless interface 630, and/or user interface 635. Wired network interface 625 may enable communications through direct machine control, a local area network, and/or the Internet (e.g., via an Ethernet connection or serial port). Wireless interface may enable communications over WI-FI, BLUETOOTH, cellular (e.g., 3G, 4G, etc.), or the like. Meanwhile, user interface 635 may include a panel with one or more switches, LEDs, LCD displays, or the like, and may enable a user to turn the monitoring system on and off, manually initiate or stop one or more tests, modify programmed tests, trigger an alarm, etc. In some embodiments, user interface 635 may be presented to a user when connecting to controller circuit 605 from a general-purpose computer or other computing device.

Controller circuit 605 may also be coupled to one or more isolation modules or panels 135a-c. While components associated with controller circuit 605 are typically installed within an enclosure at a given facility (e.g., near main distribution point 110), isolation modules 135a-b are deployed in the field along a ring ground network. Although illustrated a purpose-specific device, in alternatively embodiments at least a portion of testing and monitoring controller 600 may be implemented by a general-purpose computer or computing device connected to a relay bus, adaptor, or interface.

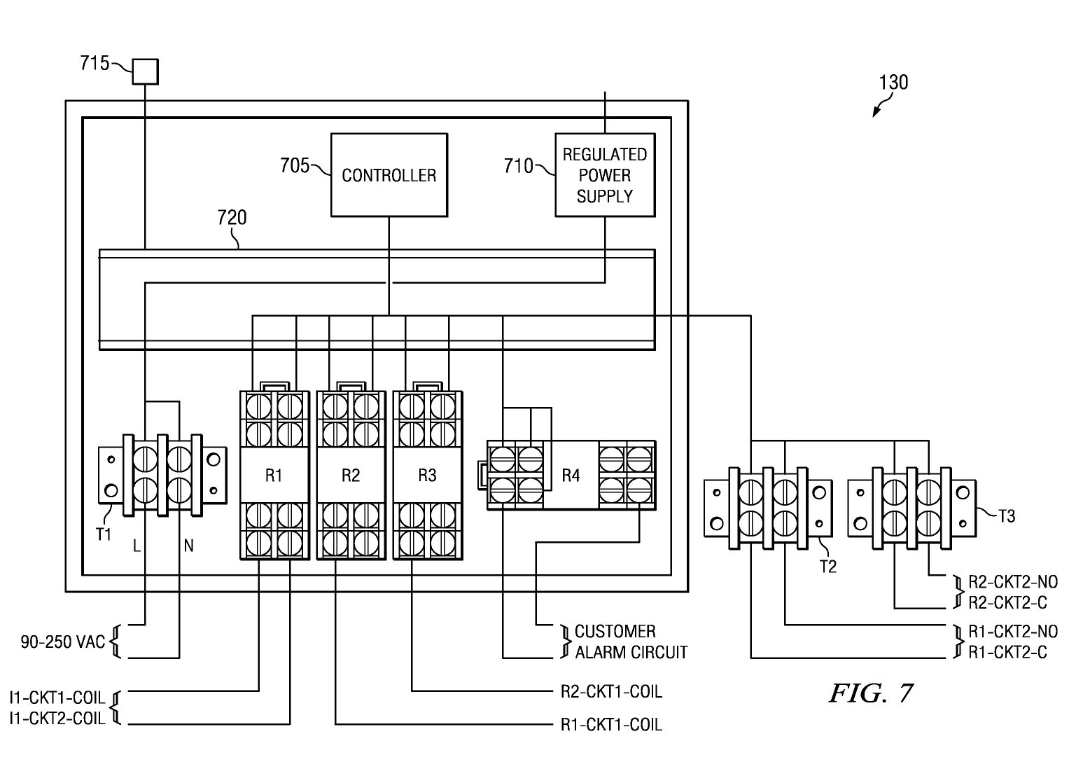

FIG. 7 is an electrical diagram of control module 130. In various embodiments, controller 700 may include one or more components of testing and monitoring controller 600 shown in FIG. 6 (e.g., controller circuit 605, etc.). Regulated power supply 710 may provide power to controller 700 and may correspond to universal power supply 610 and/or battery supply 615, whereas port 715 may provide a connection to user interface 635, also shown in FIG. 6. Controller 700 may be connected to control relays R1-R4 as wells as terminals T1-T3 through wiring 720.

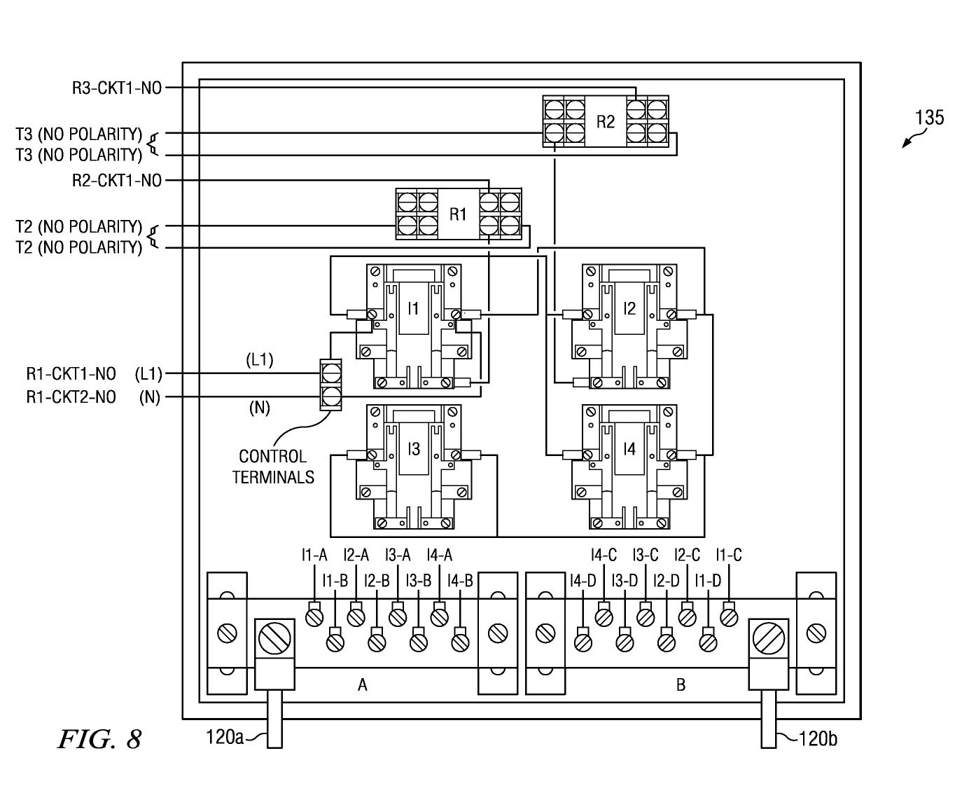

In this embodiment, terminal T1 receives power (90-250VAC) from main distribution point 110. Terminal T2 is configured to receive a DC signal from isolation panel 135 upon successful completion of a first quadrant's test, and terminal T3 is configured to receive a DC signal from isolation panel 135 upon successful completion of a second quadrant's test. Control relay R1 of control module 130 is coupled to isolation relays I1-I4 of isolation module 135 (configured to decouple a first quadrant from a second quadrant; shown in FIG. 8), control relay R2 of control module 130 is coupled to test relay R1 of isolation module 135 (configured to perform first quadrant testing; shown in FIG. 8), and control relay R3 of control module 130 is coupled to test relay R2 of isolation module 135 (configured to perform second quadrant testing; shown in FIG. 8). Alarm relay R4 is configured to activate an alarm system in case a fault is detected. In some implementations, control relays R1-R3 and alarm relay R4 within control module 130 may be 12VDC relays or the like.

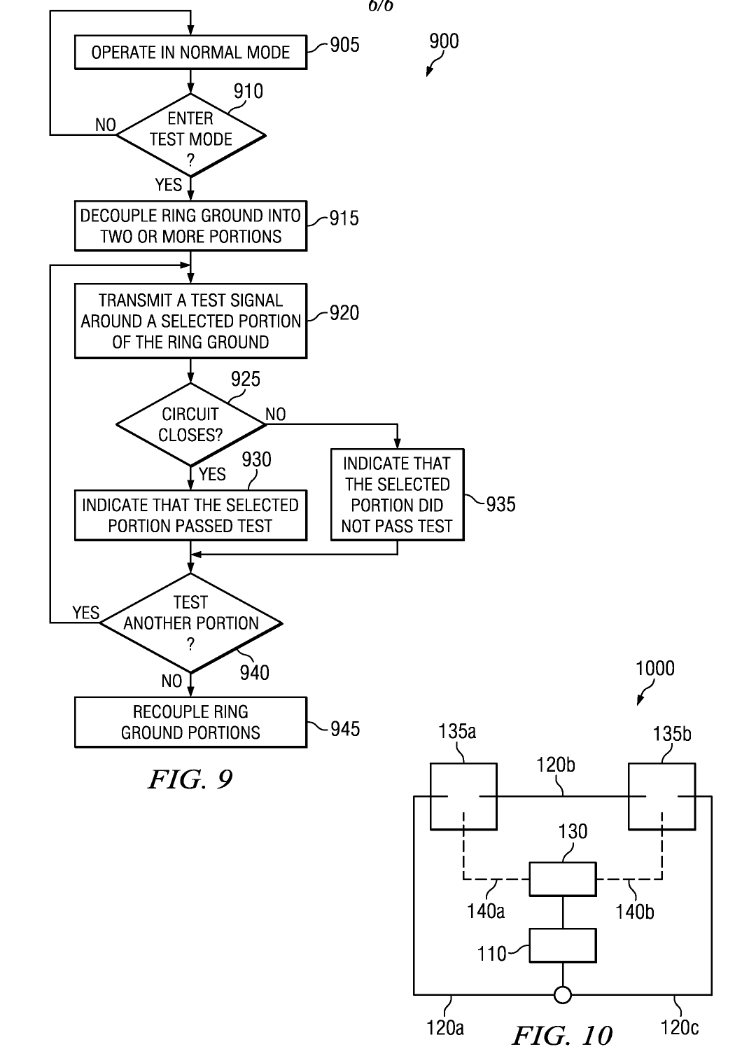

FIG. 8 is an electrical diagram of isolation module 135. In various embodiments, isolation module 135 may include one or more isolation relays 1144 connected in parallel to each other and configured to couple or decouple first and second quadrants 120a and 120b from each other. Isolation module 135 may also include test relay R1 and test relay R2. In some embodiments, each of isolation relays I1-I4, as well as test relays R1 and R2, may be 120VAC relays, 240VAC relays, or the like. Operation of these various components is described with respect to FIG. 9.

FIG. 9 is a flowchart of a ring ground testing and monitoring method 900. In some embodiments, method 900 may be performed, at least in part, by control module 130 and isolation module 135 described above. At block 905, method 900 indicates that ring ground network 120 is operating in normal mode. During normal operation, control relays R1, R2, R3, and R4 within control module 130 are de-energized, along with control relays R1 and R2 and isolation relays I1, I2, I3, and I4 within isolation module 135. In some implementations, this configuration means that control relays R1-R4 in control module 130 as well as test relays R1 and R2 in isolation panel 135 are open, and that isolation relays I1-I4 in isolation panel 135 are closed. Also, in this mode, all ground quadrants 120a and 120b are configured as a single continuous ring 120.

At block 910, control module 130 determines whether to start an electrical integrity test (e.g., a preprogrammed or scheduled test, a manual test, etc.). If not, the control returns to block 905. Otherwise, at block 915, control module 130 instructs isolation module 135 to decouple portions of the ground ring from each other. For example, at set time, a test routine may begin by I/O output to control relay R1 in control module 130. Actuation of this relay energizes isolation relays I1, I2, I3, and I4 in isolation panel 135, dividing grounding ring 120 into two separate quadrants 120a and 120b commonly connected to main grounding bus 110 of the facility's distribution center.

At block 920, control module 130 may transmit a test signal around a selected portion or quadrant of the ground ring. At block 925, method 900 may include determining whether the circuit including the selected portion closes and therefore the selected portion passes the test, indicating that it is electrically unimpaired. For example, approximately 1 second after entering test mode, control relay R2 in main module 130 may energize and send a 120VAC or 240VAC test signal to the coil of test relay R1 in isolation panel 135, thus beginning test of quadrant 120a. Upon successful completion of circuit through quadrant 120a, test relay R1 in isolation panel 135 closes, thus sending a 12-24 VDC signal to I/O of the control module 130 through terminal set T2. If the circuit does not close, the 12-24VDC signal is not received by control module 130 and the selected portion may be deemed to have failed the test.

If the selected portion passes the integrity test, method 900 may include indicating that the portion passed the test at block 930. Otherwise, method 900 may indicate the corresponding failure at block 935. These indications may be provided, for instance, as a visual indication to a user operating control module 130 (e.g., by updating status indicators such as LEDs, LCD displays, etc. on the front of a control panel), as an alert broadcast via an alarm system (e.g., using relay R4), and/or transmitted over a computer network to a remotely located computer system or the like (e.g., via interfaces 625 and/or 630).

At block 940, method 900 may include determining whether another portion of ground ring (e.g., 120b) will be tested. In a typical scenario, all quadrants of a given ring ground may be tested in some predetermined order. In those cases, control may return to block 920. For example approximately 2 seconds after the preceding operation, control relay R3 in control module 130 may energize and send a 120VAC or 240VAC test signal to the coil of test relay R2 in isolation module 135, beginning testing of quadrant 120b. Similarly as before, upon successful completion of circuit through quadrant 120b, test relay R2 in isolation module 135 closes, thus sending a 12-24 VDC signal to I/O of the control module 130 through terminal set T3.

If there are no more quadrants to be tested, then method 900 may include re-coupling the ring ground portions or quadrants together at block 945. For example, approximately 1 second after the last test, control module 130 may reset the system, thus de-energizing all relays in the main module 130 and isolation module 135 (except for relay R4 in main module 130, which remains energized until automatic or manual reset). De-energizing isolation relays I1-I4 in isolation module 135 reconnects all ground conductor quadrants 120a and 120b into a single continuous ring 120.

In some embodiments, the entire test cycle including quadrant isolation, signal injection, status update, and alarm output may take just under 5 seconds. In other embodiments, however, other durations and/or intervals may be used, thus increasing or reducing the length of the test. Moreover, when two or more isolation modules are used (i.e., more quadrants), a test may be split into different phases so that not all quadrants are tested immediately after the other. Also, in some cases, the user may wish to manually test less that all available quadrants (e.g., a single quadrant). Generally speaking, however, high frequency testing (e.g., continuous testing) is seldom needed. In a properly installed and maintained ring ground system, loss of integrity is associated with abrupt catastrophic physical damage to the buried cable; not a long-term (slow) deterioration of the system. As a result, it is relatively easy for facility managers to associate sudden failure of a ring ground system with current or recent site activities or catastrophic natural events. Also, it is desirable that ground systems have a high availability factor (e.g., two 5-second tests per day would yield a 99.988% availability).

It should be appreciated that, in implementations where two or more isolation modules are used, control module 130 may include an additional number of control relays and/or terminals. For example, a first set of control relays R1a-R3a may be used to conduct testing through a first isolation module (e.g., 135a), and a second set of control relays R1b-R3b may be employed to conduct testing through a second isolation module (e.g., 135b).

For example, FIG. 10 shows a two-isolation module—based system according to some embodiments. Control module 130 may be configured to test each of the three resulting quadrants 120a-c by decoupling those respective quadrants from ring ground 120, and injecting the testing signal through an appropriate conductor (e.g., conductor 140a may couple main module 130 to first isolation panel 135a, and conductor 140b may couple main module 130 to second isolation panel 135b). To test first quadrant 120a, main module 130 may instruct first isolation module 135a to decouple first quadrant 120a from second quadrant 120b, while second isolation module 135b may maintain second quadrant 120b coupled to third quadrant 120c. To test second quadrant 120b (between 120a and 120c), main module 130 may instruct both first and second isolation modules 135a and 135b to decouple all quadrants 120a-c from each other. Then, to test third quadrant 120c, main module 130 may instruct second isolation panel 135b to decouple second quadrant 120b from third quadrant 120c, and first isolation panel 135a may maintain first quadrant 120a coupled to second quadrant 120b.

It should be understood by a person of ordinary skill in the art in light of this disclosure that the systems and methods described herein may be readily expanded to any number of isolation panels, and thus any number of ring ground quadrants. Moreover, although control module 130 and isolation module 135 are shown as separate, distinct entities, in some embodiments a control module may be combined with an isolation module within a single panel or enclosure (e.g., installed in the field). Also, it should be noted that the specific levels of control and I/O voltage (DC) and the power voltage (AC) used throughout this description serve to illustrate a particular implementation, but in other implementations other voltage levels may be used as appropriate.

Many of the operations described herein (e.g., in connection with FIG. 9) may be implemented in hardware, software, and/or firmware, and/or any combination thereof. For example, certain operations described above (e.g., in connection with FIG. 9) may be stored as program instructions within memory 640 of FIG. 6. These program instructions may be implemented in various embodiments using any desired programming language, scripting language, or combination of programming languages and/or scripting languages (e.g., C, C++, C#, Java™, JavaScript™, Perl, etc.). When implemented in software, code segments perform the necessary tasks or operations. The processor-readable, computer-readable, or machine-readable medium may include any tangible device or medium that can store or transfer information. Examples of such a processor-readable medium include an electronic circuit, a semiconductor memory device, a flash memory, a ROM, an erasable ROM (EROM), a floppy diskette, a compact disk, an optical disk, a hard disk, etc.

The various systems and methods illustrated in the figures and described herein represent example embodiments only. These techniques may be implemented in software, hardware, or a combination thereof. The order in which each operation of a given method is performed may be changed, and various elements of the systems illustrated herein may be added, reordered, combined, omitted, modified, etc. Various modifications and changes may be made as would be clear to a person of ordinary skill in the art having the benefit of this specification. It is intended that the invention(s) described herein embrace all such modifications and changes and, accordingly, the above description should be regarded in an illustrative rather than a restrictive sense.

1. A system, comprising:
an isolation module configured to:
electrically couple a first portion of a ring ground network to a second portion of the ring ground network during operation in normal mode; and
electrically decouple the first portion of the ring ground network from the second portion of the ring ground network during operation in test mode; and
a control module coupled to the isolation module, the control module including:
an integrated circuit; and
a memory coupled to the integrated circuit, the memory configured to store program instructions executable by the integrated circuit to cause the control module to:
instruct the isolation module to operate in test mode;
control execution of an electrical integrity test of at least one of the first or second portions of the ring ground network;
indicate a result of the electrical integrity test; and
instruct the isolation module to operate in normal mode.

2. The system of claim 1, wherein the ring ground network is at least partially buried underground and configured to provide an electrical ground adapted to protect a building or equipment from electrical damage.

3. The system of claim 2, wherein the integrated circuit includes a digital signal processor (DSP), an application specific integrated circuit (ASIC), a system-on-chip (SoC) circuit, a field-programmable gate array (FPGA), a programmable logic controller (PLC), a microprocessor, or a microcontroller.

4. The system of claim 3, wherein to instruct the isolation module to operate in test mode, the program instructions are executable by the integrated circuit to further cause the control module to transmit a first electrical signal to one or more isolation relays within the isolation module, the first electrical signal adapted to open the one or more isolation relays and electrically decouple the first portion of the ring ground from the second portion of the ring ground network.

5. The system of claim 4, wherein the one or more isolation relays include one or more 120VAC or 240VAC relays connected to each other in parallel.

6. The system of claim 4, wherein to control execution of the electrical integrity test of at least one of the first or second portions of the ring ground network, the program instructions are executable by the integrated circuit to further cause the control module to:
transmit a second electrical signal to a first control relay within the isolation module, the first control relay configured to, upon receipt of the second electrical signal, return a first result signal to the control module in response to the first portion of the ground ring network being electrically unimpaired.

7. The system of claim 6, wherein the second electrical signal is a 120VAC or 240VAC signal, and wherein the first result signal is a 12-24VDC signal.

8. The system of claim 6, wherein to control execution of the electrical integrity test of at least one of the first or second portions of the ring ground network, the program instructions are executable by the integrated circuit to further cause the control module to:
transmit a third electrical signal to a second control relay within the isolation module, the second control relay configured to, upon receipt of the third electrical signal, return a second result signal to the control module in response to the second portion of the ground ring network being electrically unimpaired.

9. The system of claim 8, wherein the third electrical signal is a 120VAC or 240VAC signal, and wherein the second result signal is a 12-24VDC signal.

10. The system of claim 8, wherein to indicate the result of the electrical integrity test, the program instructions are executable by the integrated circuit to further cause the control module to:
transmit information to a remote computer over a network indicating whether at least one of the first or second portions of the ground ring network is electrically unimpaired.

11. The system of claim 10, wherein to instruct the isolation module to operate in normal mode, the program instructions are executable by the integrated circuit to further cause the control module to:
transmit a fourth electrical signal to the one or more isolation relays within the isolation module, the fourth electrical signal adapted to close the one or more isolation relays and electrically couple the first portion of the ring ground to the second portion of the ring ground network.

12. A tangible storage medium having program instructions stored thereon that, upon execution by a ring ground monitoring system, cause the ring ground monitoring system to:
transmit a signal instructing an isolation module to electrically decouple a first portion of a ring ground network from a second portion of the ring ground network;
cause execution of an electrical test of the first portion of the ring ground network; and
receive a result of the electrical test, the result indicative of whether the first portion of the ground ring network is electrically impaired.

13. The tangible storage medium of claim 12, the program instructions, upon execution by the ring ground monitoring system, further cause the ring ground monitoring system to:
cause execution of another electrical test of the second portion of the ring ground network; and
receive another result of the another electrical test, the another result indicative of whether the second portion of the ground ring network is electrically impaired.

14. The tangible storage medium of claim 12, the program instructions, upon execution by the ring ground monitoring system, further cause the ring ground monitoring system to:
transmit a signal instructing the isolation module to electrically couple the first portion of the ring ground network to the second portion of the ring ground network.

15. The tangible storage medium of claim 12, the program instructions, upon execution by the ring ground monitoring system, further cause the ring ground monitoring system to:
provide a visual indication of whether first portion of the ground ring network is electrically impaired to a user.

16. The tangible storage medium of claim 12, the program instructions, upon execution by the ring ground monitoring system, further cause the ring ground monitoring system to:
transmit information of whether the first portion of the ground ring network is electrically impaired over a computer network to a remotely located computer system.

17. A method comprising:
performing, by an isolation module,
receiving, from a ring ground monitoring system, a signal instructing the isolation module to electrically decouple a portion of the ring ground network from another portion of the ring ground network;
electrically decoupling the portion of the ring ground network from the another portion of the ring ground network;
performing, at the control of the ring ground monitoring system, execution of an electrical integrity test of the portion of the ring ground network; and
providing, to the ring ground monitoring system, a result of the electrical test, the result indicative of whether the portion of the ground ring network is electrically impaired.

18. The method of claim 17, wherein performing execution of the electrical test of the portion of the ring ground network further comprises receiving an alternating current signal at a relay within the isolation module.

19. The method of claim 18, wherein providing the result of the electrical test further comprises providing a direct current (DC) signal to the ring ground monitoring system upon the relay closing in response to completion of an electrical circuit, the electrical circuit including the portion and excluding the another portion of the ring ground network.

20. The method of claim 17, further comprising:
performing, by the isolation module,
receiving, from the ring ground monitoring system, a signal instructing the isolation module to electrically couple the first portion of the ring ground network to the second portion of the ring ground network; and
electrically coupling the first portion of the ring ground network to the second portion of the ring ground network.
